(19) United States
(12) Patent Application Publication
(10) Pub. No.: US 2008/0032446 A1
(43) Pub. Date: Feb. 7, 2008

(54) COMBINATION HEAT DISSIPATION DEVICE WITH TERMINATION AND A METHOD OF MAKING THE SAME

(76) Inventors: Steve Wood, Munich (DE); Simon Muff, Mering (DE); Anton Legen, Munich (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 11/462,662

(22) Filed: Aug. 4, 2006

(51) Int. Cl. H01L 21/00

(52) U.S. Cl. 438/106

(57) ABSTRACT

An integrated circuit assembly including an integrated circuit device electrically connected to a signal line, and method of making the same. The invention also includes a heat dissipation device thermally coupled to the integrated circuit device and a termination resistor electrically connected to the signal line and the heat dissipation device.

### BACKGROUND OF THE INVENTION

1. Field of the Invention

The present invention relates generally to the field of integrated circuit devices and more particularly to memory devices with a combination heat sink and termination. The present invention also relates to memory modules and a memory module fitted with the combination heat sink in termination device.

2. Description of the Related Art

Recently an increase in the operation speed of integrated circuit devices including memory devices is rapidly advancing. With an increased integration density of integrated circuit devices the amount of heat generated correspondingly increases. Additionally, increased demand for downsizing modules accommodating microelectronic components including integrated circuit devices complicates both the need to remove excessive heat generated by integrated circuit devices and how to accomplish heat removal within an increasingly limited area. Thus the overall heat density associated with microelectronic devices and modules increases. Moreover many integrated circuit devices including memory devices and chip type circuit components are mounted on a printed circuit board so that a number of components mounted on a module has a tendency to increase.

Another drawback stemming from the higher and higher operating frequencies required of increased density integrated circuit devices as well as increased density integrated circuit devices on modules is the electrical phenomena termed reflections. As an electrical signal travels down the signal line it eventually reaches the end of that signal line. When the electrical signals reach the end of that signal path or signal line the electrical signal is reflected back, thus interfering with other signals still traveling along the signal line. One example of this type of negative feedback is reflections caused by a memory module connector pin or a DRAM package pin operating at high frequencies. Sometimes this may be noticed by an increase in noise and a degradation of the signal integrity. Increased noise or increased reflected signals will interfere with the real data on the signal line and may cause a potential signal loss and also further data corruption.

One technique for reducing the effects of reflections on an integrated circuit device is to terminate the signal line. Special components are used that make the signal line appear electrically as if it were infinite in length, thus causing any propagated signals to terminate with no reflections. Although various termination schemes may be employed, a common termination scheme is to use a resistor coupled to a voltage source or a ground potential. Another common termination scheme is to use a pull-up resistor coupled to a voltage source, Vtt, that is typically half the voltage corresponding to a logic one on a signal line or bus. However, employing conventionally designed resistors for facilitating termination of the signal line has some limitations, one of which is the relatively large surface area of a module or an integrated circuit that is consumed by the termination circuitry. The termination circuitry increases the cost of the module and also reduces the area available for other resources.

Both issues of increased heat density of integrated circuit devices and potentially increased reflections along the signal line of integrated circuit devices are not uncommon in the field of multi-chip modules. Generally multi-chip modules may be designed to include more than one type of integrated circuit and other chip-like components. Examples of multi-chip modules are so-called memory modules which include single inline memory modules or SIMM and dual inline memory modules or DIMM. Memory modules include circuit boards such as printed circuit boards or PCBs that typically have chips or integrated circuits on one or both sides of the module. Termination circuitry or terminations may be positioned on the memory module, for example on the circuit board carrying the integrated circuit devices or memory devices. Furthermore, termination circuitry may also be positioned on the integrated circuit devices themselves. Terminations are positioned between the signal line to be terminated and a reference voltage node such as a ground voltage, a power supply voltage, or some other voltage type.

The present invention is directed to combining the need of a heat dissipation device and a termination to overcome or at least reduce the effects of one or more the problems set forth above. Moreover, the present invention permits an integrated circuit device manufacturer or a multi-chip module manufacturer to provide their own termination devices suited to their particular electrical specifications. Conventional practice sometimes requires an integrated circuit device manufacturer or multi-chip module manufacturer to impedance match their devices with another manufacturer's termination circuitry. Thus, the present invention increases the flexibility of integrated circuit devices and multi-chip modules for use in various computer systems that utilize different computer components having multiple manufacturers, where the termination circuitry for each manufacturer's devices can be determined and fabricated by the individual manufacturer without upsetting the electrical interconnections between various manufacturers components. Nor must an individual manufacturer rely on another manufacturer to provide the correct termination circuitry. In sum, the present invention may permit increased density of integrated circuit devices on a multi-chip module that operates at higher frequencies.

### SUMMARY OF THE INVENTION

One aspect of the present invention is seen in an integrated circuit assembly, including an integrated circuit device electrically connected to a signal line. The integrated circuit assembly also includes a heat dissipation device thermally coupled to the integrated circuit device and a termination resistor electrically connected to the signal line and the heat dissipation device.

Another aspect of the present invention is seen in an apparatus for radiating heat and terminating and electrical signal including a combination heat dissipation device and a termination resistor. According to another aspect of the present invention there is a method of making an apparatus for radiating heat and terminating an electrical signal wherein the method includes steps as described in the following. In an initial step a base material is provided for forming an apparatus for radiating heat. Next, a heat dissipation device including a termination resistor is formed from the base material.

Another aspect of the present invention is seen in an integrated circuit assembly including a die stack comprising a plurality of electrically connected integrated circuits placed on each other. The integrated circuits are electrically connected to a vertical signal line. The integrated circuit assembly also includes a heat dissipation device on top of the die stack in thermally coupled to the die stack. A termination resistor is thermally coupled to the heat dissipation device and electrically connected to the vertical signal line and the heat dissipation device.

### BRIEF DESCRIPTION OF THE DRAWINGS

The above recited features of the present invention will become clear from the following description taking in conjunction with the accompanying drawings in which like reference numerals identify like elements. It is to be noted however, that the accompanying drawings illustrate only typical embodiments of the present invention and are therefore not to be considered limiting of the scope of the invention. The present invention may admit other equally effective embodiments. The present invention will be described below in more details with reference to the embodiments and drawings.

FIG. 1 shows a diagrammatic plan view of an integrated circuit assembly, in this case a conventional memory module.

FIG. 2 shows a diagrammatic cross-sectional view of an integrated circuit assembly.

FIG. 3 shows a diagrammatic cross-sectional view of an integrated circuit assembly according to one aspect of the present invention.

FIG. 4 shows a top view of an apparatus for dissipating heat and terminating an electrical signal.

FIG. 5 shows a top view of an apparatus for dissipating heat and terminating an electrical signal according to another embodiment of the present invention.

FIG. 6 shows a top view of an apparatus for dissipating heat and terminating an electrical signal according to another embodiment of the present invention.

FIG. 7 shows a top view of an apparatus for dissipating heat and terminating an electrical signal according to another embodiment of the present invention.

FIG. 8 shows a perspective view of a termination resistor according to an embodiment of the present invention.

FIG. 9 shows a diagrammatic plan view of an integrated circuit assembly fitted with a heat dissipation device according to another embodiment of the present invention.

### DETAILED DESCRIPTION OF THE PREFERRED EMBODIMENT

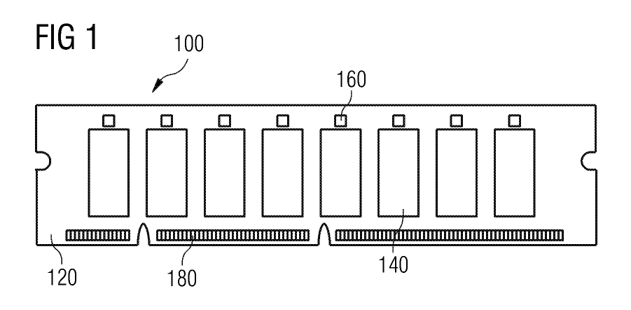

These aspects of the present invention can provide particular advantages for an improved integrated circuit device and improved integrated circuit assemblies by combining features of a heat dissipation device with a termination. Turning now to FIG. 1 a diagrammatic plan view of an integrated circuit assembly, in this case a conventional memory module 100, is shown. The memory module shown is just one example of an integrated circuit assembly such as is common in multi-chip modules. The memory module 100 comprises integrated circuit devices 140, in this case conventional memory devices such as DRAM or Dynamic Random Access Memory. A typical memory module conventionally has a plurality of memory devices 140. Next to the memory devices 140 are termination resistors 160 on the printed circuit board 120. The printed circuit board 120 has an array of contact pads 180 provided along a side edge of each face of the printed circuit board 120 for electrically connection with an appropriate mating socket. FIG. 1 thus illustrates a typical embodiment of an integrated circuit assembly which may employ the present invention and is meant to orient the reader to a preferred application of the present invention.

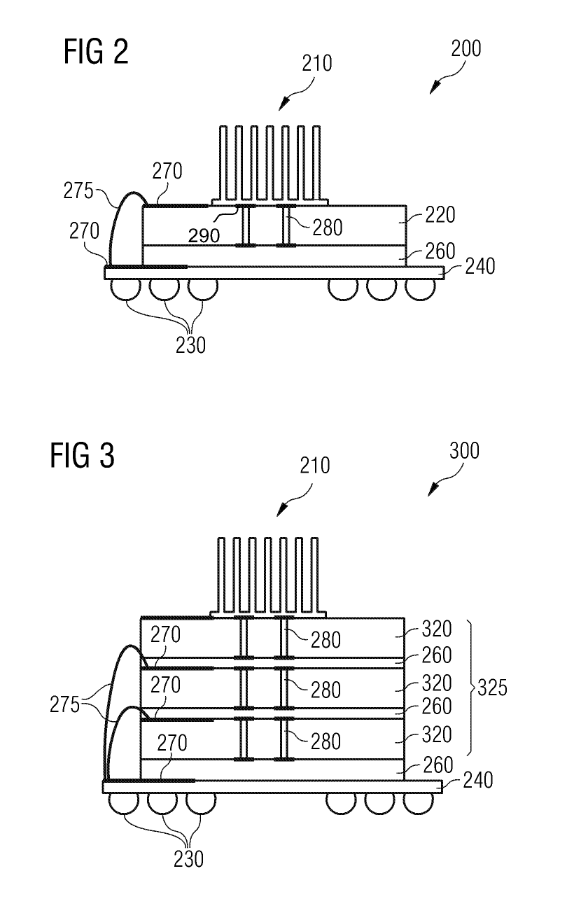

FIG. 2 shows a diagrammatic cross-sectional view of an integrated circuit assembly 200. In this embodiment the integrated circuit assembly 200 is represented here as an integrated circuit package, including a heat dissipation device 210. The integrated circuit assembly 200 includes an integrated circuit device 220 electrically connected to a signal line 280. In this embodiment the signal line 280 is represented here by thru hole vias, typically comprising a silicon via. The heat dissipation device 210 is thermally coupled to the integrated circuit device 220. A termination resistor 290 (one example referenced) is electrically connected to the signal line 280 and the heat dissipation device 210. As a result, the heat dissipation device 210 also serves an electrical functionality in addition to its heat dissipating function.

The integrated circuit assembly 200 may also include a substrate 240 with an intermediate layer 260 for joining two separate components when forming an integrated circuit package, such as joining the integrated circuit device 220 and the substrate 240. The substrate 240 may also include a means for connecting the integrated circuit assembly 200 to a printed circuit board, here represented as a ball grid array or BGA 230. Contact pads 270 on the integrated circuit device 220 and the substrate 240 are electrically connected through a means such as wire bond 275. The heat dissipation device 210 may be a conventional fin heat sink as illustrated in FIG. 2. Additionally, the heat dissipation device 210 may comprise other heat sink designs, including both passive designs, such as pin fin heat sinks, and active heat sink designs, such as so-called fan sinks.

Turning now to FIG. 3 another embodiment of the present invention is illustrated, showing a diagrammatic cross-sectional view of an integrated circuit assembly 300, here represented as a die stack package. Since the integrated circuit assemblies of FIGS. 2 and 3 are similar, not all elements are described anew and are denoted by identical reference signs. An integrated circuit assembly 300 includes a die stack 325 wherein the die stack comprises a plurality of electrically connected integrated circuits 320 that are placed on each other. The integrated circuits 320 are connected to each other through a vertical signal line 280, in this case represented by silicon thru vias. An intermediate layer 260 joins two separate components, for example a substrate 240 and an integrated circuit 320 or two integrated circuits 320. A heat dissipation device 210 is on top of and thermally coupled to the die stack 325.

A termination resistor (not shown) is also thermally coupled to the heat dissipation device 210. Moreover, the termination resistor is electrically connected to a signal line 280 and the heat dissipation device 210. Possible termination resistor configurations within the scope of the invention will be shown in the subsequent Figures. Contact pads 270 may also electrically connect the die stack 325 to a substrate 240 through a connecting means such as a wire bond 275. The substrate 240 may also include a means for connecting the integrated circuit assembly 300 to a printed circuit board, here represented as a ball grid array or BGA 230. The heat dissipation device 210 may be on top of the die stack 325. Moreover, the termination or termination resistor will be dimensionally pre-structured to form a specific resistance. This feature of the present invention will also be shown in subsequent Figures. The integrated circuits may comprise any type of integrated circuit, for example digital signal processors, read only memory, microprocessors, central processing unit (CPU) type integrated circuits, or memory devices such as DRAM.

The integrated circuit assembly 300 may also replace any of the integrated circuit devices 140 of the memory module 100 shown in FIG. 1. In this embodiment of the invention, the chip type resistors 160 may no longer be necessary, freeing up the surface area of the PCB 120 for larger integrated circuit assemblies or integrated devices, thereby increasing the density of components mounted to the PCB. Stacked multi-chip modules or die stacks minimize the board-space footprint necessary to represent a given function, and both die back-grinding and advanced assembly techniques minimize their height thereby enabling increased densities.

In such an embodiment, the combination heat dissipation device 210 and termination resistor (not shown) may serve as a termination point for one type of a signal line, for example a transmission line in the PCB, commonly referred to as a stripline, which is a specific transmission line on a PCB where the signal trace is buried within the PCB. In one embodiment, the memory module 100 includes memory devices comprising die stack components of DRAM where at least one of the die stack components comprises the integrated circuit assembly 300 shown in FIG. 3. The heat dissipation device 210 and termination resistor (not shown) may terminate a so called fly-by command/access/control bus architecture such as is conventionally used in double data rate III or DDR3 type memory modules, an example of which is DDR3 SDRAM or synchronous dynamic random access memory. The signal in a fly-by bus architecture flies by a first DRAM device, a second DRAM device, and so on until the last DRAM device and terminates at the end. Thus, the last DRAM device on a memory module would may be of the type illustrated in FIG. 3 and include the heat dissipation device 210 and termination resistor (not shown). Bus reflections may then be minimized enabling the busses to operate at much higher frequencies.

Other types of memory modules useful for the invention include fully buffered DIMM or FBD type memory modules. DDR3 and FBD type memory modules may operate at higher frequencies, thus increasing the likelihood of reflections. In these type of embodiments, one of the memory devices 140 that comprises the integrated circuit assembly 300, may be referred to as the termination chip. One possible advantage to such an embodiment is that not only may the chip type resistors 160 be unnecessary, thus freeing up coveted surface area for larger memory components and increased density, but because of the termination resistor, the termination chip theoretically burns the most power which is also nearest the heat dissipation device. Consequently, most of the heat generated by the operating memory module will be efficiently dissipated by the heat dissipation device.

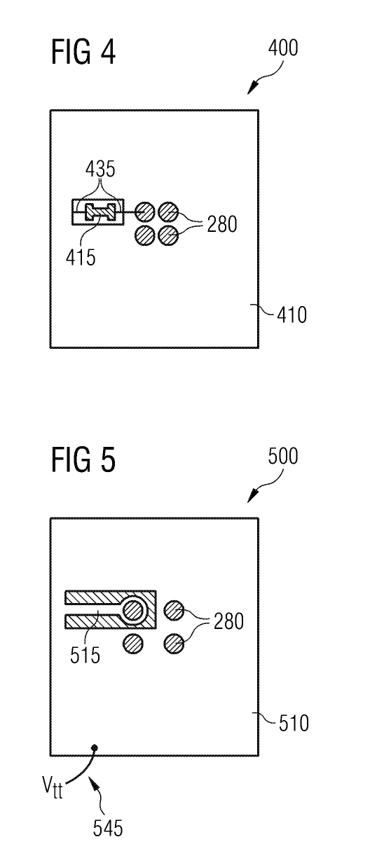

In FIGS. 4 through 7, various embodiments of the present invention are shown. In particular, various embodiments of an apparatus for dissipating heat and terminating an electrical signal are illustrated. The combination heat dissipation device and termination of the integrated circuit assemblies shown in FIGS. 2 and 3 may comprise any of the apparatuses illustrated in FIGS. 4 through 7. In each of the FIGS. 4 through 7, the apparatus for dissipating heat and terminating an electrical signal is shown as if it were on a die stack and a signal line of the integrated circuit assembly below it were visible. Of course, the top surface area of the integrated circuit assembly may be larger than the bottom surface area of the apparatus although for simplicity, such an embodiment is not illustrated here. The main purpose of FIGS. 4 through 7 is to illustrate various embodiments of the apparatus for dissipating heat and terminating and electrical signal when in use on an integrated circuit device or package.

In each of the FIGS. 4 through 7, an apparatus for radiating heat and terminating an electrical signal is shown. The apparatus comprises a heat dissipation device and a termination resistor. In one embodiment, the apparatus includes a heat dissipation device framing the termination resistor. The termination resistor itself may comprise various shapes that are may be dimensionally pre-structured to provide a specific resistance which may be achieved by varying the length, height, and width of the termination resistor. Examples of such shapes are a beam shape, a folded shape, or a corrugated shape. In one embodiment, the termination resistor shape will be long, compared to the width, such as occurs in a folded or corrugated shape. The cross-section of a resistor may be specifically defined but the length varied to achieve a desired resistance. Moreover an apparatus for radiating heat and terminating an electrical signal may include contact terminals to electrically connect to an integrated circuit device and/or a termination potential such as ground.

Turning to FIG. 4, a top view of an apparatus for dissipating heat and terminating an electrical signal is shown. The apparatus configuration in FIG. 4 is may be employed as the combination heat dissipation device and termination resistor shown in FIGS. 2 and 3, though any of the apparatus's configurations as illustrated in FIGS. 5 through 7 may also be employed. The exact dimensions and configuration of the heat dissipation device may be determined by the particular heat dissipation needs of the integrated circuit assembly and thus, will vary with the exact integrated circuit design and use specifications. As seen in FIG. 4, a square outlining an apparatus 400 for dissipating heat and terminating an electrical signal comprises a heat dissipation device 410 and a termination resistor 415. The heat dissipation device 410 may be a conventional fin heat sink. In one embodiment, the heat dissipation device 410 also houses the termination resistor 415.

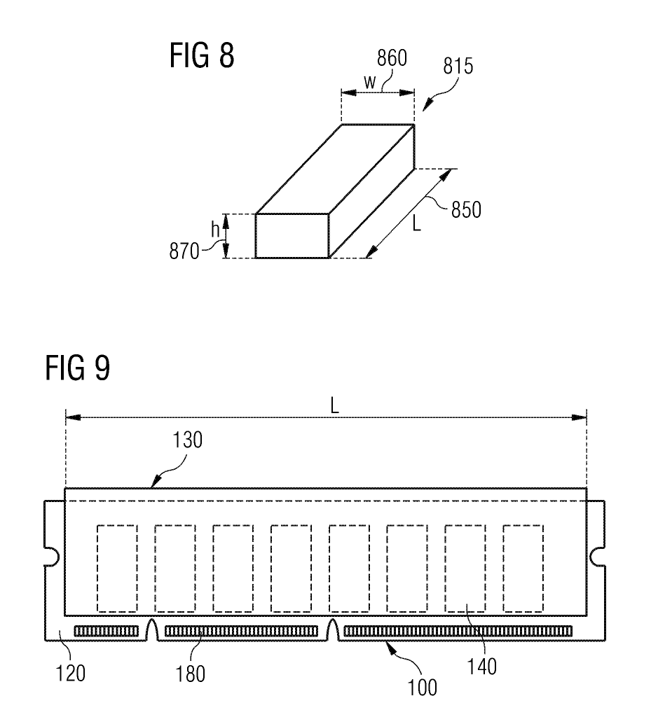

The termination resistor 415 is electrically connected to a signal line 280 and the heat dissipation device 410. A transmission line 435 in this embodiment, electrically connects the heat dissipation device 410 and the signal line 280 to the termination resistor 415. In one embodiment, contact terminals on the apparatus 400 are used to electrically connect an integrated circuit device to the termination resistor 415 and a termination potential such as ground. The termination resistor 415 is may be a beam shape as shown in FIG. 4. The exact height, length, and width or in other words the exact dimensions of the termination resistor 415 may be predetermined to form a specific resistance. This feature of the invention will also be described and illustrated in greater detail in FIG. 8. The signal line 280 is here represented as silicon thru vias, such as those that are shown in FIGS. 2 and 3.

FIG. 5 shows a top view of an apparatus 500 for dissipating heat and terminating an electrical signal according to another embodiment of the present invention. Since the apparatus is similar to that shown in FIG. 4 not all elements are described again and are denoted by identical reference signs. In this embodiment of the present invention, an apparatus 500 for dissipating heat and terminating a signal comprises a heat dissipation device 510 and a termination resistor 515. In the embodiment shown in FIG. 4, the heat dissipation device 410 and termination resistor 415 were represented as discrete components. In the embodiment shown in FIG. 5, the apparatus 500 is formed such that a portion of the heat dissipation device 510 forms the termination resistor 515. In one embodiment, the heat dissipation device 510 also houses the termination resistor 515. The termination resistor 515 here comprises a beam shape as well. Additionally, the termination resistor 515 is electrically connected to a signal line 280 and to the heat dissipation device 510. Moreover, the apparatus 500 may also comprise a termination potential 545 which may comprise a ground termination or a voltage termination potential. The termination resistor 515 may also be thermally coupled to the heat dissipation device 510.

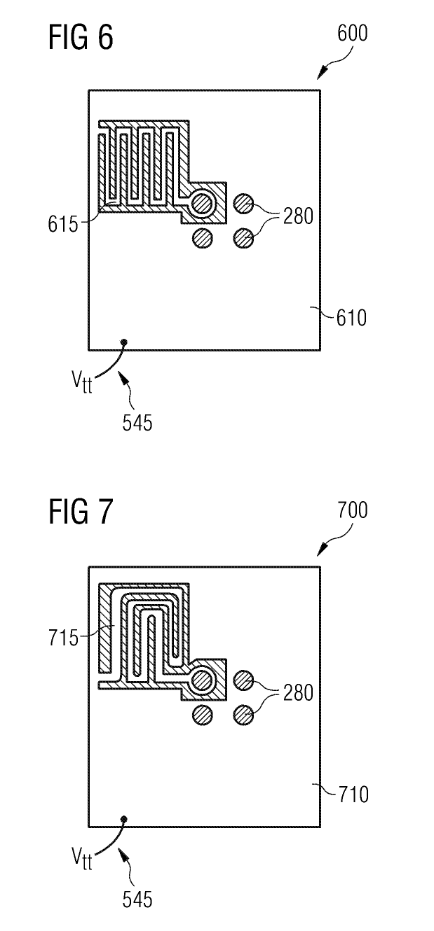

Turning now to FIG. 6 another embodiment of the present invention is shown. A top view of an apparatus 600 for dissipating heat and terminating an electrical signal is illustrated. The apparatus 600 comprises a heat dissipation device 610 and termination resistor 615. In this embodiment of the present invention, the termination resistor 615 comprises a corrugated shape and is also a portion of the heat dissipation device 610. In one embodiment, the heat dissipation device 610 also houses the termination resistor 615. The apparatus 600 may also comprise a termination potential 545 which may comprise a ground termination or a voltage termination potential. The termination resistor 615 may also be thermally coupled to the heat dissipation device 610.

FIG. 7 shows a top view an apparatus 700 for dissipating heat and terminating an electrical signal including a combination heat dissipation device 710 and termination resistor 715. In this embodiment of the present invention, the termination resistor 715 comprises a folded shape and is electrically connected to a signal line 280 in the heat dissipation device 710. The apparatus 700 may also comprise a termination potential 545 which may comprise a ground termination or a voltage termination potential. Additionally, the termination resistor 715 is may be thermally coupled with the heat dissipation device 710 as also illustrated in FIGS. 5, 6 and 7. In one embodiment, the heat dissipation device 710 also houses the termination resistor 715.

One advantage of an apparatus for dissipating heat and terminating an electrical signal where the combination heat dissipation device houses the termination resistor is that most of the heat generated by the integrated circuit assembly will be localized at the termination resistor. Because the termination resistor is the primary source of heat, is framed by the heat dissipation device, and may even be a portion of the heat dissipation device itself, excess heat may be more efficiently transferred to the heat dissipation device and as a result, the air surrounding the heat dissipation device, thus cooling the integrated circuit assembly efficiently. This is especially so as integrated circuit assemblies function at higher and higher frequencies. Moreover higher frequencies in integrated circuit assemblies may cause increased signal degradation due to reflections in the signal line. Accordingly, the present invention may be particularly suited or tailored for the higher and higher frequencies demanded of multi-chip modules.

An apparatus for dissipating heat and terminating an electrical signal as shown in FIGS. 4, 5, 6 and 7 may be fabricated by the following method. First a based material is provided and then a heat dissipation device including the termination resistor is formed from the base material. The base material is may be a metal such as copper, aluminum or silver. Other materials conventionally used for a heat dissipation and as a termination resistor may also be used. The forming step may comprise any conventional methods to shape a material such as laser cutting, casting, etching, machining, stamping, milling and cutting. These methods and any others conventionally used to form heat dissipation devices such as fin heat sinks or pin fin heat sinks, may be employed to create the apparatus for dissipating heat and terminating an electrical signal. Additionally, the heat dissipation device may also be a plate fin or an elliptical fin heat sink. FIG. 8 further explains how to determine the shape of the termination resistor to be formed as part of the apparatus.

Turning to FIG. 8 a termination resistor 815 is shown. The length 850, width 860 and height 870 of the beam shaped termination resistor 815 may be may be pre-structured to provide a specific resistance. In one embodiment, the termination resistor shape will be long, compared to the width, such as occurs in a folded or corrugated shape. Additionally, the cross-section of a resistor may be specifically defined but the length varied to achieve a desired resistance. One example of how to determine the specific resistance of a termination resistor is based on the following expression:

$$R = r \times \frac{L}{A}$$

where,

R=resistance

r=specific resistance

L=length

A=cross-sectional area or height multiplied by width.

An example of such calculations in order to determine the specific resistance is shown in table 1.

TABLE 1

| w/ | | | |
|---|---|---|---|
| mm | h/mm | L/mm | R/Ohm |
| .01 | .01 | 5 | 1389 |
| .02 | .02 | 5 | 347 |
| .03 | .03 | 5 | 154 |
| .04 | .04 | 5 | 87 |
| .05 | .05 | 5 | 56 |
| 0.1 | 0.1 | 5 | 14 |
| 0.2 | 0.2 | 5 | 3 |

Each of the dimensions are given in millimeters and the specific resistance or r is a physical constant which intrinsic to the material in use. For example the specific resistance or r of aluminum is 0.0278 Ω×mm²/m and was used in determining the resistance or R of the results indicated in Table 1. Thus, by using the above formula the termination resistor of the present invention may be dimensionally pre-structured when forming the apparatus for radiating heat and terminate it in an electrical signal. By merely increasing the length while maintaining a defined cross-sectional area will correspondingly increase the resistance of a terminating resistor. The corollary to which is that increasing or decreasing the cross-sectional area while maintaining a set length also decreases or increases respectively, the resistance of a terminating resistor, an example of which is recorded in Table 1.

FIG. 9 shows a diagrammatic plan view of an integrated circuit assembly fitted with a heat dissipation device according to another embodiment of the present invention. In this embodiment the integrated circuit assembly 100 is a multi-chip module, such as a memory module, including a plurality of integrated circuit devices 140, such as memory devices or DRAM. A heat dissipation device 130 is fitted to cover the integrated circuit assembly or memory module 100. The heat dissipation device 130 includes a termination resistor (not shown) that is electrically connected to a signal line (not shown) in the integrated circuit assembly 100 and the heat dissipation device 130.

The present invention may be used for conventional memory modules such as SIMMs or DIMMs, particularly the FBD or DDR3 type memory modules that utilize high frequencies and increased densities of integrated circuit devices. The present invention however should not be interpreted to be limited to only memory type modules. Other types of modules that use integrated circuit devices may also be within the scope of the invention. For example, any central processing unit or CPU type modules, microprocessor modules, graphics type modules, and even sound modules, and any of their integrated circuit devices, are within the scope of the invention. In short, any type of integrated circuit assemblies or devices that seeks to minimize unwanted signal reflections and require heat dissipation may utilize the invention.

The preceding description only describes advantageous exemplary embodiments of the invention. The features disclosed therein and the claims and the drawings can therefore be essential for the realization of the invention in its various embodiments both individually and in any combination. While the foregoing is directed to embodiments of the present invention other and further embodiments of this invention may be devised without departing from the basic scope of the invention. The scope of the present invention being determined by the claims that follow.

What is claimed is:

1. An integrated circuit assembly, comprising:
an integrated circuit device electrically connected to a signal line;
a heat dissipation device thermally coupled to the integrated circuit device; and
a termination resistor electrically connected to the signal line and the heat dissipation device.

2. The integrated circuit assembly of claim 1 wherein the integrated circuit device comprises a die stack comprising a plurality of electrically connected integrated circuit devices placed on each other.

3. The integrated circuit assembly of claim 2 wherein the heat dissipation device is on top of the die stack.

4. The integrated circuit assembly of claim 1 wherein the termination resistor is thermally coupled to the heat dissipation device.

5. The integrated circuit assembly of claim 1 wherein the heat dissipation device is a component of the termination resistor.

6. The integrated circuit assembly of claim 1 wherein the termination resistor has a beam shape.

7. The integrated circuit assembly of claim 1 wherein the termination resistor has a folded shape.

8. The integrated circuit assembly of claim 1 wherein the termination resistor has a corrugated shape.

9. The integrated circuit assembly of claim 1 wherein heat dissipation device houses the termination resistor.

10. The integrated circuit assembly of claim 1 wherein the termination resistor is dimensionally pre-structured to provide a specific resistance.

11. The integrated circuit assembly of claim 1 wherein the heat dissipation device is electrically connected to a termination potential.

12. An apparatus for dissipating heat and terminating an electrical signal, comprising:
a heat dissipation device and a termination resistor in physical contact with the heat dissipation device, the termination resistor being adapted to terminate the electrical signal.

13. The apparatus of claim 12 wherein the heat dissipation device houses the termination resistor.

14. The apparatus of claim 12 wherein the termination resistor has a beam shape.

15. The apparatus of claim 12 wherein the termination resistor has a folded shape.

16. The apparatus of claim 12 wherein the termination resistor has a corrugated shape.

17. The apparatus of claim 12 further comprising contact terminals.

18. The apparatus of claim 12 wherein the termination resistor is dimensionally pre-structured to provide a specific resistance.

19. A method of making an apparatus for radiating heat, the method comprising:
providing a base material; and
forming a heat dissipation device including a termination resistor from the base material; the termination resistor being adapted to terminate an electrical signal from an integrated circuit.

20. The method of claim 19 wherein the forming step comprises any of the following: laser cutting, casting, etching, machining, stamping, milling, and cutting.

21. The method of claim 19 wherein the termination resistor is formed into a beam shape.

22. The method of claim 19 wherein the termination resistor is formed into a folded shape.

23. The method of claim 19 wherein the termination resistor is formed into a corrugated shape.

24. The method of claim 19 wherein the heat dissipation device is formed to frame the termination resistor.

25. The method of claim 19 wherein the termination resistor is dimensionally structured to provide a specific resistance.

26. An integrated circuit assembly, comprising:
a die stack comprising a plurality of electrically connected integrated circuits placed on each other, the integrated circuits electrically connected to a signal line vertically disposed through the die stack;
a heat dissipation device on top of and thermally coupled to the die stack, and;
a termination resistor thermally coupled to the heat dissipation device, and electrically connected to the signal line and the heat dissipation device.

27. The integrated circuit assembly of claim 26 wherein the die stack is on a substrate.

28. The integrated circuit assembly of claim 26 wherein the heat dissipation device is dimensionally pre-structured to form a termination resistor of specific resistance.

29. The integrated circuit assembly of claim 26 wherein the heat dissipation device comprises the termination resistor.

30. The integrated circuit assembly of claim 26 wherein the termination resistor comprises a beam shape.

31. The integrated circuit assembly of claim 26 wherein the termination resistor comprises a folded shape.

32. The integrated circuit assembly of claim 26 wherein the termination resistor comprises a corrugated shape.

33. The integrated circuit assembly of claim 26 wherein heat dissipation device houses the termination resistor.

34. The integrated circuit assembly of claim 26 wherein the heat dissipation device is electrically connected to a termination potential.
